(19) United States
(12) Patent Application Publication
(10) Pub. No.: US 2012/0120682 A1
(43) Pub. Date: May 17, 2012

(54) ILLUMINATION DEVICE WITH LIGHT GUIDE COATING

(75) Inventors: Teruo Sasagawa, Los Gatos, CA (US); Brian W. Arbuckle, Danville, CA (US); William Cummings, Clinton, WA (US); Ion Bita, San Jose, CA (US); Kebin Li, (US); Rashmi Rao, Santa Clara, CA (US)

(73) Assignee: QUALCOMM MEMS Technologies, Inc., San Diego, CA (US)

(21) Appl. No.: 13/279,204

(22) Filed: Oct. 21, 2011

Related U.S. Application Data
(60) Provisional application No. 61/414,328, filed on Nov. 16, 2010.
(60) Provisional application No. 61/489,178, filed on May 23, 2011.

(51) Int. Cl. F21V 7/00; B23P 11/00; G03F 7/20; F21V 8/00; B05D 5/06

(52) U.S. Cl. 362/624; 362/627; 427/162; 430/299; 29/428

(57) ABSTRACT

This disclosure provides systems, methods and apparatus for providing illumination by using a light guide to distribute light. In one aspect, the light guide includes a light turning film over an optically transmissive supporting layer. The light turning film may be formed of a material deposited in the liquid state. The light turning film may be formed of a photodefinable material, which may be glass, such a spin-on glass, or may be a polymer. In some other implementations, the glass is not photodefinable. The light turning film may have indentations that define light turning features and a protective layer may be formed over those indentations. The protective layer may also be formed of a glass material, such as spin-on glass. The light turning features in the light guide film may be configured to redirect light out of the light guide, for example, to illuminate a display.

### REFERENCE TO RELATED APPLICATION

This application claims the priority benefit under 35 U.S.C. §119(e) of U.S. provisional Application No. 61/414,328, filed Nov. 16, 2010, entitled “ILLUMINATION DEVICE WITH PASSIVATION LAYER,” and U.S. provisional Application No. 61/489,178, filed May 23, 2011, entitled “ILLUMINATION DEVICE WITH LIGHT GUIDE COATINGS,” both of which are assigned to the assignee hereof. The disclosures of the prior applications are considered part of this disclosure and are incorporated by reference in their entireties.

### TECHNICAL FIELD

This disclosure relates to illumination devices having light guides to distribute light, including illumination devices for displays, and to electromechanical systems.

### DESCRIPTION OF THE RELATED TECHNOLOGY

Electromechanical systems (EMS) include devices having electrical and mechanical elements, actuators, transducers, sensors, optical components (for example, minors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Reflected ambient light is used to form images in some display devices, such as those using pixels formed by interferometric modulators. The perceived brightness of these displays depends upon the amount of light that is reflected towards a viewer. In low ambient light conditions, light from an artificial light source is used to illuminate the reflective pixels, which then reflect the light towards a viewer to generate an image. To meet market demands and design criteria, new illumination devices are continually being developed to meet the needs of display devices, including reflective and transmissive displays.

### SUMMARY

The systems, methods and devices of the disclosure each have several innovative aspects, no single one of which is solely responsible for the desirable attributes disclosed herein.

One innovative aspect of the subject matter described in this disclosure can be implemented in an illumination system. The illumination system includes a light guide having an optically transmissive supporting layer; and a light turning film on the supporting layer. The light turning film is depositable in the liquid phase on the supporting layer. A plurality of light turning features are formed in indentations on a major surface of the light turning film. The light turning film may be formed of a glass material. The glass may be a spin-on glass. The spin-on glass may be photodefinable in some implementations. In some implementations, the material forming the light turning film may be a photodefinable polymer.

Another innovative aspect of the subject matter described in this disclosure can be implemented in an illumination system. The illumination system includes a light guide, which includes an optically transmissive supporting layer; and a means for accommodating indentations for light turning features. The means for accommodating indentations is depositable in a liquid state. The means for accommodating indentations may be a light turning film formed of spin-on glass or a photo-definable polymer.

Yet another innovative aspect of the subject matter described in this disclosure can be implemented in a method for forming an illumination system. The method includes providing an optically transmissive supporting layer; depositing a liquid material on the support layer to form a light turning film; and defining indentations in the light turning film to form a plurality of light turnings features in the light turning film. Depositing the liquid material can include performing a spin-on deposition. Defining the indentations can include exposing the light turning film to light through a reticle and subsequently exposing the light turning film to a development etch to form the indentations.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9A shows an example of a cross-section of an illumination system.

FIG. 9B shows an example of a cross-section of a light turning feature.

FIG. 10 shows an example of a cross-section of an illumination system provided with a passivation layer disposed over a light guide.

FIG. 11 shows an example of a cross-section of an illumination system provided with optical decoupling layers.

FIG. 12 shows a plot of reflectivity versus thickness for a passivation layer situated directly on a light guide.

FIG. 13 shows a plot of reflectivity versus thickness for a passivation layer situated directly on a light turning feature.

FIG. 14 shows an example of a cross-section of an illumination system with multiple passivation layers.

FIGS. 15A and 15B show an example of a cross-section of a light turning feature and a light guide having an overlying passivation layer.

FIGS. 16A and 16B show an example of a cross-section of an illumination system with a light turning feature and light guide having an overlying patterned passivation layer.

FIG. 17 shows an example of a cross-section of an illumination system provided with a multi-layer light guide.

FIGS. 18A-18F show examples of cross-sections of an illumination system at various stages in a process sequence for manufacturing the illumination system.

FIG. 19 shows an example of a flow diagram illustrating a manufacturing process for an illumination system.

FIGS. 20A and 20B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (for example, video) or stationary (for example, still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (for example, e-readers), computer monitors, auto displays (for example, odometer display, etc.), cockpit controls and/or displays, camera view displays (for example, display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, parking meters, washers, dryers, washer/dryers, parking meters, packaging (for example, electromechanical systems (EMS), MEMS and non-MEMS), aesthetic structures (for example, display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

In some implementations, an illumination system is provided with a light guide to distribute light. The light guide can include a light turning film over a supporting layer. In some implementations, the light turning film may be formed of a material that can be deposited on the support layer as a liquid. The material forming the light turning film can be a photodefinable material, which may be glass, such a spin-on glass, or may be a polymer. In some other implementations, the light turning film may be formed of a glass, such as a spin-on glass, that is not photodefinable.

The light turning film may include indentations that define light turning features that can be configured to redirect light, propagating within the light guide, out of the light guide. For example, the sides of the indentations forming the light turning features may form facets that reflect light out of the light guide. In some implementations, the sides of the indentations may be coated with a reflective coating. An overlying protective layer, such as a passivation layer, may be provided over the reflective coating to protect it from chemically reactive agents in the ambient. In some implementations, the protective layer also may be formed of a glass material, such as spin-on glass. In some implementations, the light redirected by the light turning features may be applied to illuminate a display, such as a reflective display, which may be an interferometric modulator display.

Particular implementations of the subject matter described in this disclosure can be implemented to realize one or more of the following potential advantages. Typical light turning films may be formed of chemical vapor deposited materials. Such films can be costly to manufacture due to the relative slowness of the deposition process and the resulting low throughput for manufacturing light guides. In addition, the etch processes used to define light turning features in such light turning films typically have low etch rates, thereby further decreasing throughput. The use of photodefinable materials (including photodefinable glass materials) or non-photodefinable glass materials allows the light turning film to be formed by a relatively fast bulk deposition, for example, the deposition of material in the liquid phase, such as a spin-on coating process, in some implementations. In some implementations, the light turning film may be relatively quickly etched. For example, the photodefinable materials may be etched using a development etched. Such a wet etch may remove material more quickly than a dry etch. Also, because the light turning film may be photodefinable, a separate mask formation and pattern transfer step is not required to define indentations in the light turning film. As a result, manufacturing throughput can be increased, thereby reducing manufacturing costs. In addition, the cost of the materials may be lower than that of chemical vapor deposited materials, thereby further reducing manufacturing coats.

One example of a suitable MEMS or electromechanical systems (EMS) device, to which the described methods and implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

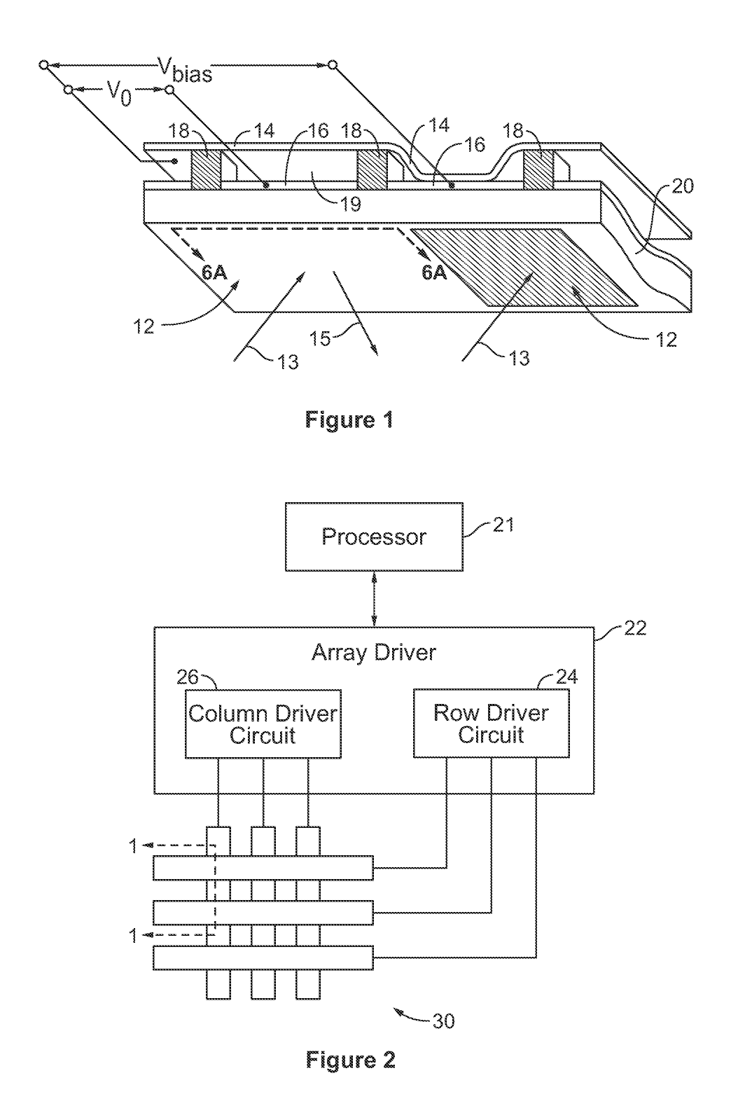

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, for example, to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when actuated, reflecting light outside of the visible range (for example, infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows indicating light 13 incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, for example, chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (for example, of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 can be approximately 1-1000 um, while the gap 19 can be less than <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, for example, voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example, a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

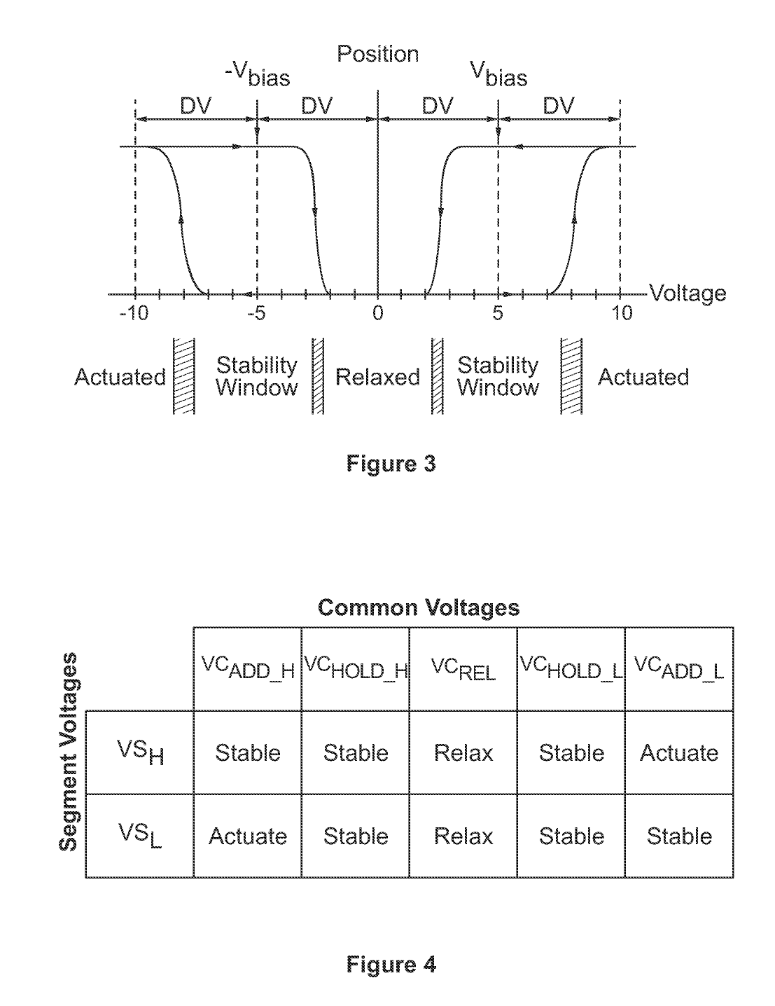

FIG. 3 shows an example of a diagram illustrating a movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, for example, about a 10-volt potential difference to cause the movable reflective layer, or minor, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about, in this example, 10 volts, and pixels that are to be relaxed are exposed to a voltage difference of near zero volts. After addressing, the pixels are exposed to a steady state or bias voltage difference of approximately, in this example, 5 volts such that they remain in the previous strobing state. In this example, after being addressed, each pixel sees a potential difference within the “stability window” of about 3-7 volts. This hysteresis property feature enables the pixel design, such as the one illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

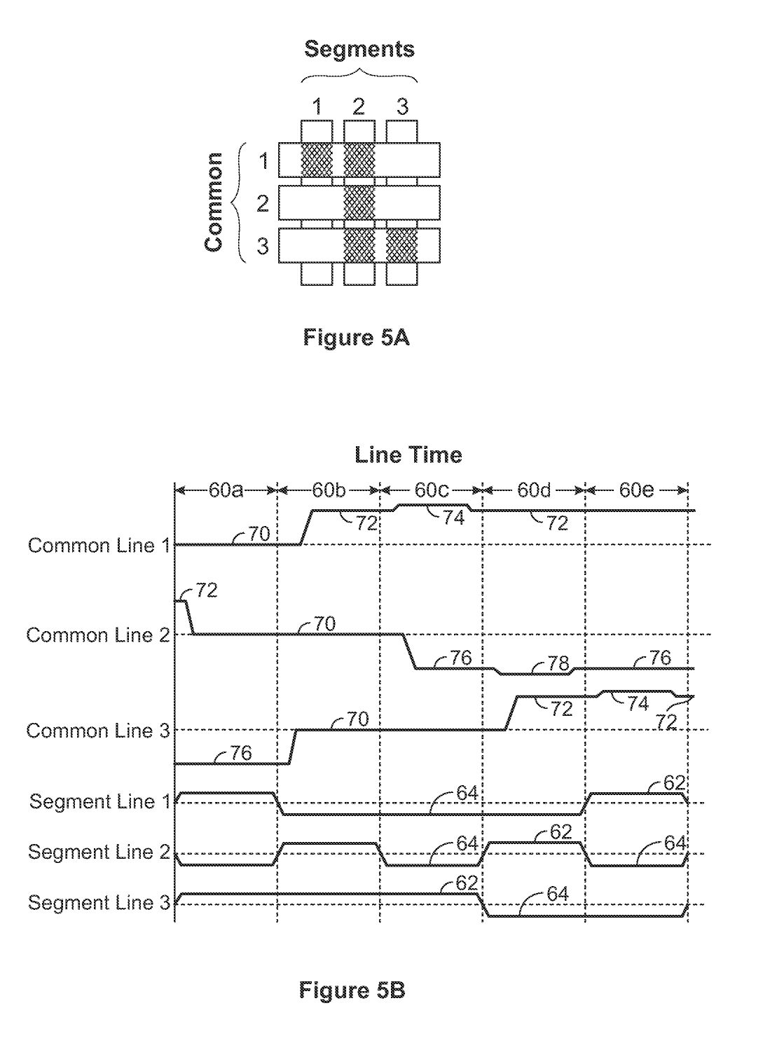

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, for example, 3×3 array of FIG. 2, which will ultimately result in the line time 60e display arrangement illustrated in FIG. 5B. The actuated modulators in FIG. 5A are in a dark-state, i.e., where a substantial portion of the reflected light is outside of the visible spectrum so as to result in a dark appearance to, for example, a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

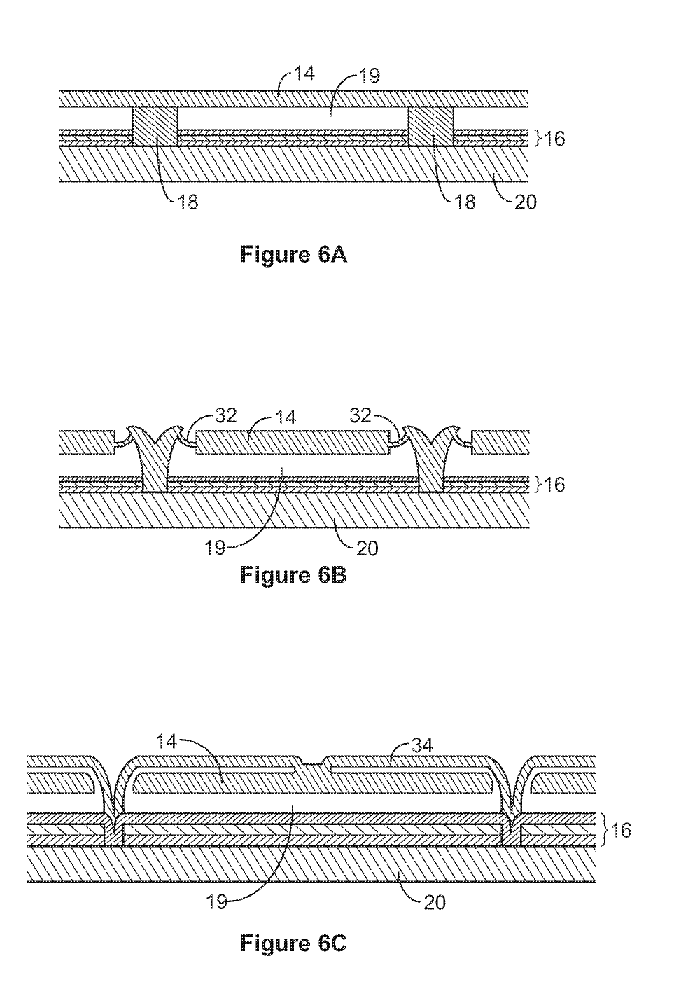

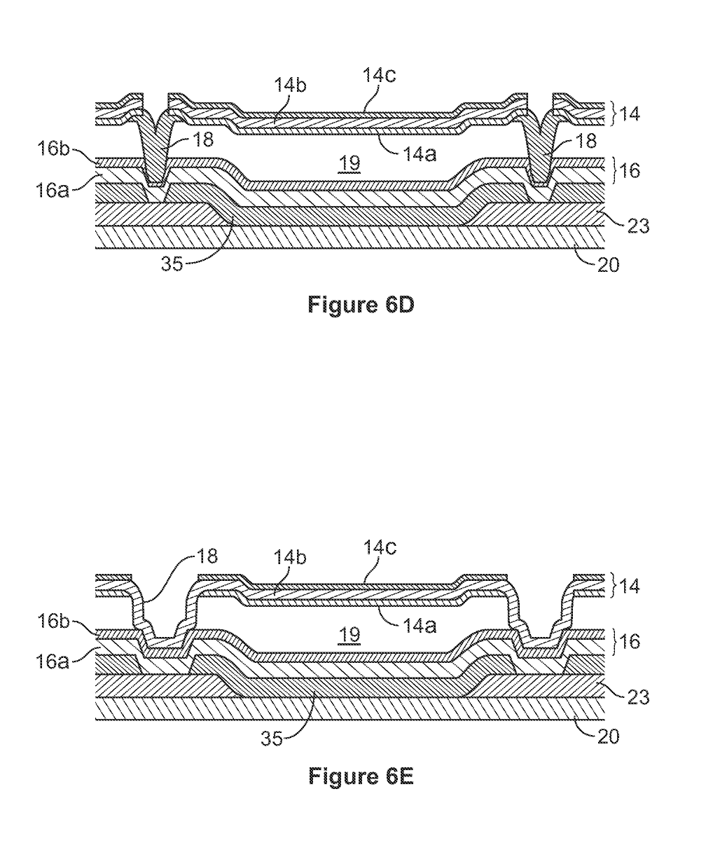

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures.

FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (for example, between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, patterning.

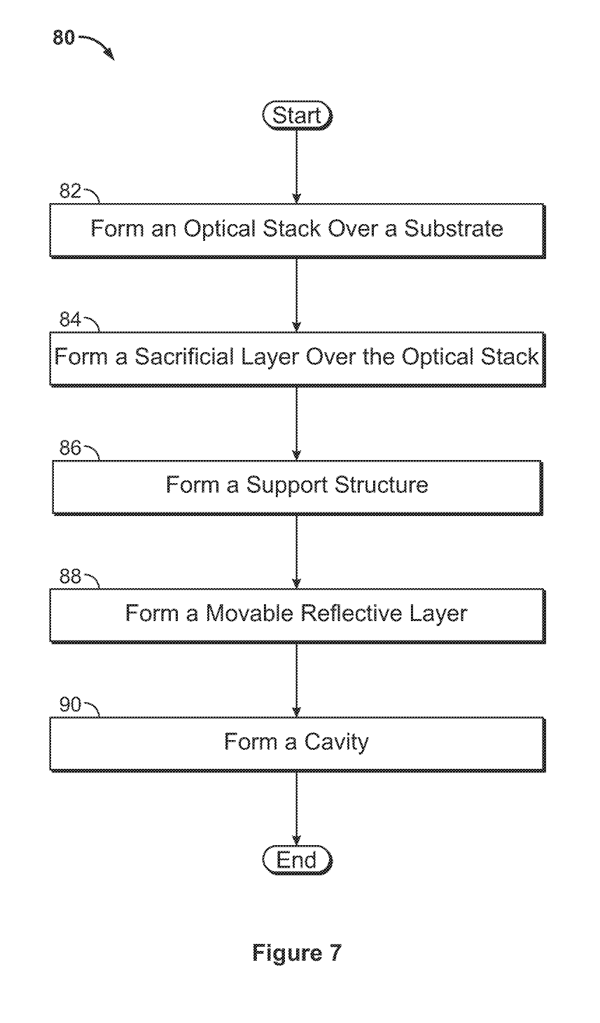

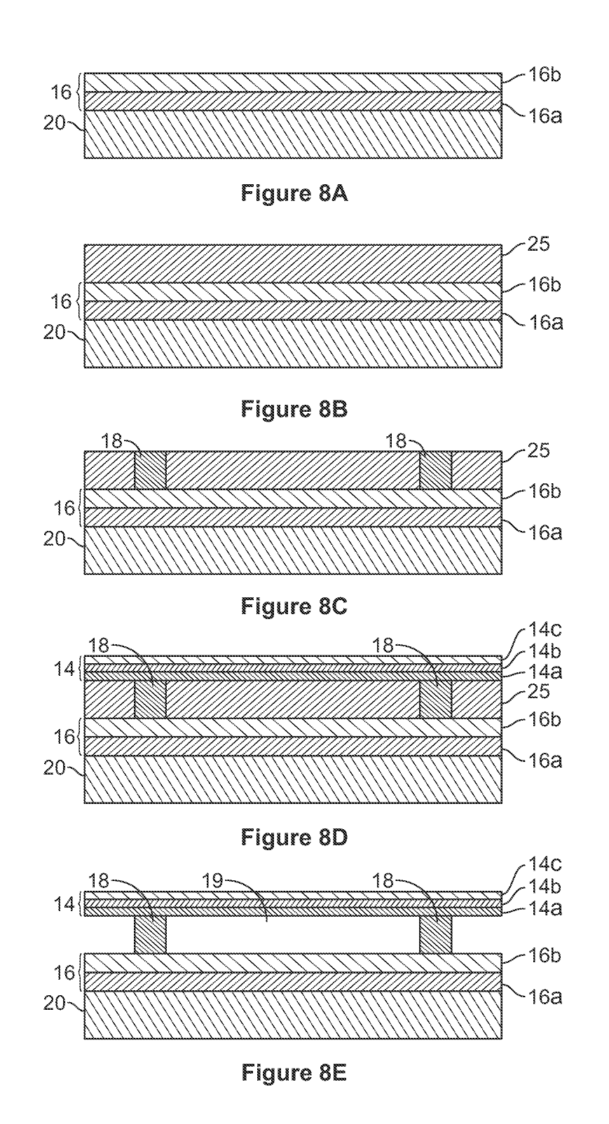

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, for example, interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, for example, cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (for example, one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (for example, at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, for example, sputtering), plasma-enhanced chemical vapor deposition (PECVD), thermal chemical vapor deposition (thermal CVD), or spin-coating.

The process 80 continues at block 86 with the formation of a support structure for example, a post 18 as illustrated in FIGS. 1, 6 and 8C. The formation of the post 18 may include patterning the sacrificial layer 25 to form a support structure aperture, then depositing a material (for example, a polymer or an inorganic material, for example, silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, for example, reflective layer (for example, aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, for example, cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, for example, by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, for example wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Because reflective displays, such as those with interferometric modulator pixels, use reflected light to form images, it may be desirable to augment the ambient light to increase the brightness of the display in some environments. This augmentation may be provided by an illumination system in which light from a light source is directed to the reflective display, which then reflects the light back towards a viewer.

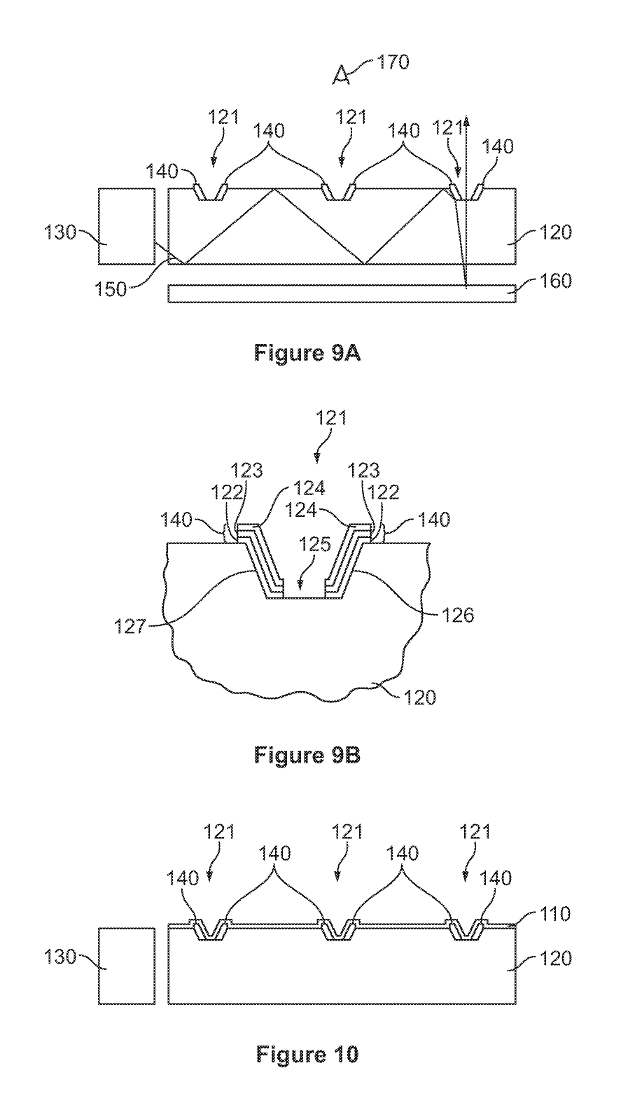

FIG. 9A shows an example of a cross-section of an illumination system. A light guide 120 receives light from a light source 130. A plurality of light turning features 121 in the light guide 120 is configured to redirect light (for example, light ray 50) from the light source 130 back towards an underlying reflective display 160. Reflective pixels in the reflective display 160 reflect that redirected light forward towards a viewer 170. In some implementations, the reflective pixels can be an IMOD 12 (FIG. 1).

With continued reference to FIG. 9A, the light guide 120 may be a planar optically transmissive panel disposed facing and parallel to a major surface of the display 160 such that incident light passes through the light guide 120 to the display 160, and light reflected from the display 160 also passes back through the light guide 120 to the viewer 170.

The light source 130 may include any suitable light source, for example, an incandescent bulb, a edge bar, a light emitting diode (“LED”), a fluorescent lamp, an LED light bar, an array of LEDs, and/or another light source. In certain implementations, light from the light source 130 is injected into the light guide 120 such that a portion of the light propagates in a direction across at least a portion of the light guide 120 at a low-graze angle relative to the surface of the light guide 120 aligned with the display 160 such that the light is reflected within the light guide 120 by total internal reflection (“TIR”). In some implementations, the light source 130 includes a light bar. Light entering the light bar from a light generating device (for example, a LED) may propagate along some or all of the length of the bar and exit out of a surface or edge of the light bar over a portion or all of the length of the light bar. Light exiting the light bar may enter an edge of the light guide 120, and then propagate within the light guide 120.

The light turning features 121 in the light guide 120 direct the light towards display elements in the display 160 at an angle sufficient so that at least some of the light passes out of the light guide 120 to the reflective display 160. The light turning features 121 may include one or more layers configured to increase reflectivity of the turning feature 121 facing away from the viewer 170 and/or function as a black mask from the viewer side. These layers may be referred in the aggregate as coating 140.

FIG. 9B shows an example of a cross-section of a light turning feature in which the coating 140 includes a plurality of layers. In certain implementations, the coating 140 of the turning features 121 may be configured as an interferometric stack having: a reflective layer 122 that re-directs light propagating within the light guide 120, a spacer layer 123, and a partially reflective layer 124 overlying the spacer layer 123. The spacer layer 123 is disposed between the reflective layer 122 and the partially reflective layer 124 and defines an optical resonant cavity by its thickness.

The interferometric stack can be configured to give the coating 140 a dark appearance, as seem by the viewer 170. For example, light can be reflected off of each of the reflective layer 122 and partially reflective layer 124, with the thickness of the spacer 123 selected such that the reflected light interferes destructively so that the coating 140 appears black or dark as seem from above by the viewer 170 (FIG. 9A).

The reflective layer 122 may, for example, include a metal layer, for example, aluminum (Al), nickel (Ni), silver (Ag), molybdenum (Mo), gold (Au), and chromium (Cr). The reflective layer 122 can be between about 100 Å and about 700 Å thick. In one implementation, the reflective layer 122 is about 300 Å thick. The spacer layer 123 can include various optically transmissive materials, for example, air, silicon oxy-nitride (SiOₓN), silicon dioxide (SiO₂), aluminum oxide (Al₂O₃), titanium dioxide (TiO₂), magnesium fluoride (MgF₂), chromium (III) oxide (Cr₃O₂), silicon nitride (Si₃N₄), transparent conductive oxides (TCOs), indium tin oxide (ITO), and zinc oxide (ZnO). In some implementations, the spacer layer 123 is between about 500 Å and about 1500 Å thick. In one implementation, the spacer layer 123 is about 800 Å thick. The partially reflective layer 124 can include various materials, for example, molybdenum (Mo), titanium (Ti), tungsten (W), chromium (Cr), etc., as well as alloys, for example, MoCr. The partially reflective 124 can be between about 20 and about 300 Å thick in some implementations. In one implementation, the partially reflective layer 124 is about 80 Å thick.

With continued reference to FIG. 9B, because light is principally redirected to the display 160 off of the sides 126 and 127 of the light turning feature 121, in some implementations, in the area between theses sides, the coating 140 may be provided with an opening 125 through which light can travel. The opening 125 can facilitate the propagation of ambient light to the display 160 and/or the propagation of reflected light to the viewer 170.

It has been found that metal layers, such as the reflective coating 140 and the partially reflecting layer 124, in some implementations, can corrode or otherwise undergo undesired reactions. Without being limited by theory, it is believe that these undesired reactions occur due to moisture or gases (for example, oxidants) from the ambient diffusing to and reacting with the reflective coating 140 and/or layer 124. These reactions can change the materials properties of the reflective coating 140 (for example, degrade the reflectivity of the coating and layers) and thereby degrade the desired functionality of the coating 140 and/or layer 124.

FIG. 10 shows an example of a cross-section of an illumination system provided with a passivation layer 110 disposed over the light guide 120. Light source 130 is configured to inject light into the light guide 120. In some implementations, the passivation layer 110 is disposed directly on portions of the light guide 120, such as portions of the light guide extending between the light turning features 121. The passivation layer 110 may also be disposed directly on coating 140 of the light turning features 121. As illustrated, the light turning features 121 may be formed as indentations in the light guide 120 and the passivation layer 110 may extend substantially conformally over the top major surface of the light guide 120. In some implementations, the ratio of a thickness of the conformal passivation layer 110 at a bottom of a light turning feature 121 to the thickness of the conformal passivation layer 110 at the sidewalls of that light turning feature 121 may be about 5:1, about 3:1, about 2:1, about 1.5:1, or about 1:1. Such levels of thickness uniformity can provide advantages for forming an anti-reflective coating while providing passivation, as discuss herein.

With continued reference to FIG. 10, the passivation layer 110 may be a moisture barrier. In some implementations, the passivation layer 110 has a moisture transmission coefficient of about 1 g/m²/day or less, about 0.01 g/m²/day or less, or about 0.0001 g/m²/day or less. The passivation layer 110 may be of a suitable thickness to provide barrier properties against moisture and/or ambient gases. Thicknesses of about 50 nm or more, or about 75 nm or more have been found to provide particular advantages for isolation against the environment and for added optical functionality (for example, anti-reflective properties).

In some implementations, when exposed to an environment of 85° C. with 85% relative humidity, the passivation layer 110 prevents corrosion in reflective coating 140 for a duration of at least about 200 hours, or at least about 500 hours, or at least about 1000 hours. In some implementations, the corrosion prevention is at such a level that operation of the device is not impaired, such that the device meets its operating specifications. For example, as the partially reflective layer 124 in the coating 140 corrodes, the black-mask properties of the coating 140 decrease and an increase in ambient reflection off of the coating 140 (due, for example, to reflection from the layer 122) can occur. In some implementations, corrosion of the layer 124 is prevented to such an extent that the increase in perceived reflection off of the coating 140 is about 20% or less, about 10% or less, or about 5% or less after 500 hours in an environment at 85° C. with 85% relative humidity. In some implementations, these benefits are achieved for reflective coating 140 that includes a 50 nm reflective layer 122 of Al, a 72 nm spacer layer 123 of silicon oxide, and a 5 nm partially reflective layer 124 of MoCr (FIG. 9B) in a light turning feature 10 um wide.

The passivation layer 110 may be formed of an optically transmissive material, including optically transmissive dielectric materials which may be advantageous for electrically isolating electrical structures underlying the passivation layer 110. Examples of suitable materials for the passivation layer 110 include silicon oxide (SiO₂), silicon oxynitride (SiON), MgF₂, CaF₂, Al₂O₃, or mixtures thereof. In some implementations, the passivation layer 110 is formed of a spin-on glass.

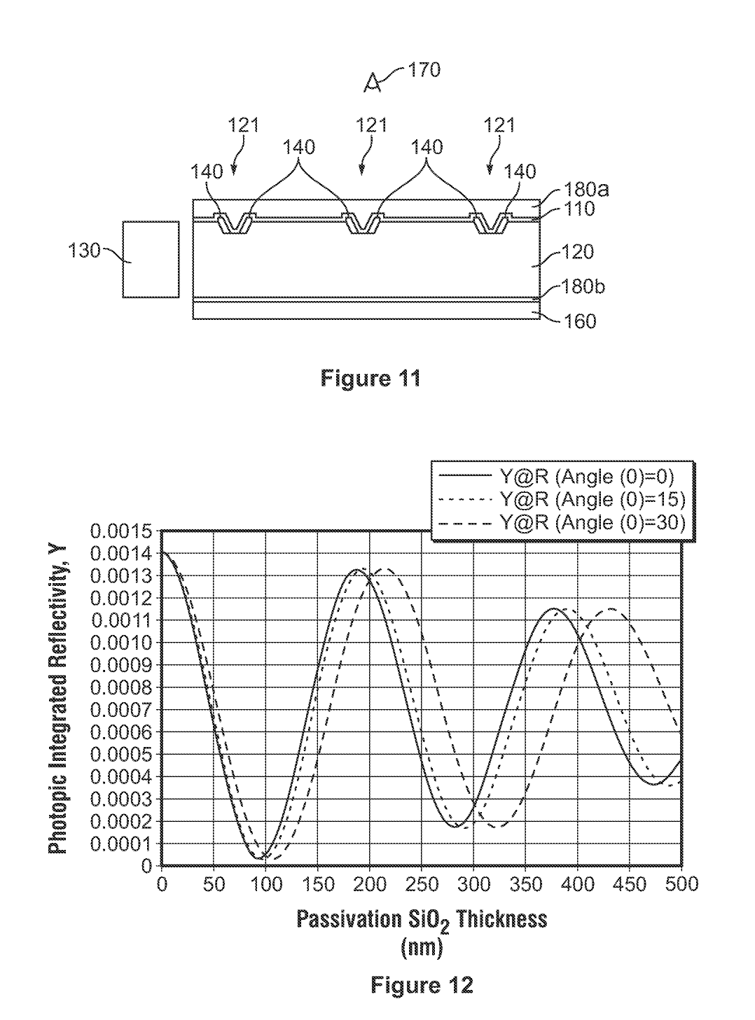

With reference to FIG. 11, one or more optical decoupling layers may be provided to facilitate the propagation of light within the light guide 120. FIG. 11 shows an example of a cross-section of an illumination system provided with optical decoupling layers. For example, an optical decoupling layer 180a may be provided over the passivation layer 110. In some implementations, the optical decoupling layer 180a has a lower refractive index than either the passivation layer 110 or the light guide 120. The lower refractive index encourages total internal reflection off the interface between the passivation layer 110 and the optical decoupling layer 180a, thereby facilitating the propagation of light by total internal reflection across the light guide 120. In some implementations, the optical decoupling layer 180a may provide additional functionality. For example, the layer 180a may be formed of a material that provides mechanical protection for the passivation layer 110 and the light guide 120. Examples of suitable materials for the optical decoupling layer 180a include MgF₂, CaF₂, UV-curable epoxies, polymeric coatings, organosiloxane coatings, silicone adhesives, and other similar materials with a refractive index smaller than about 1.48, or smaller than about 1.45, or smaller than about 1.42 in the visible spectrum.

With continued reference to FIG. 11, in some implementations, another optical decoupling layer 180b may be provided underlying the light guide 120. This other optical decoupling layer 180b may also have a lower refractive index than the light guide 120 to thereby facilitate total internal reflection at the interface of the layer 180b with the light guide 120. The layer 180b may be formed of the same or a different material than the layer 180a. In some other implementations, the layer 180b is omitted and a gap (for example, an air gap) provides a low refractive index medium to facilitate total internal reflection at the lower major surface of the light guide 120.

With continued reference to FIG. 11, in some implementations, the passivation layer 110 is configured to provide anti-reflective properties. For example, the refractive index and thickness of the passivation layer 110 may be selected to allow the layer 110 to function as an interference anti-reflective coating. In some implementations, the refractive index of the passivation layer 110 is between the refractive index of the optical decoupling layer 180a and the refractive index of the light guide 120 (or the layer of the light guide 120 immediately adjacent the passivation layer 110, where the light guide 120 includes multiple layers). For example, the refractive index of the passivation layer 110 may be derived using the following equation:

RI_{PS}=\sqrt{RI_{LG}×RI_{ODL}}

where
RI_{PS} is the refractive index of the passivation layer;
RI_{LG} is the refractive index of the light guide; and
RI_{ODL} is the refractive index of the optical decoupling layer.
   Thus, in some implementations, the refractive index of the passivation layer 110 may be about RI_{PS}. In some implementations, the refractive index of the passivation layer 110 is within 10% of RI_{PS}, or within 5% of RI_{PS}.

In one example, an optical decoupling layer 180a of silicone having a refractive index of 1.42 may be disposed directly over a passivation layer 110 formed of silicon oxide having a refractive index of 1.47, which is disposed on a light guide 120, which includes a layer of SiON directly underlying the passivation layer 110, the SiON layer having a refractive index of 1.52. In some implementations, the silicone may be a silicone adhesive coating. The optical decoupling layer 180a may directly contact the passivation layer 110, which may directly contact the light guide 120. In some implementations, the refractive index of the passivation layer 110 is within 0.1 of the optical decoupling layer 180a, the light guide 120, or both the optical decoupling layer 180a and the light guide 120. In some implementations, the refractive index of the optical decoupling layer 180a is about 0.05 or more, or about 0.1 or more, less than the refractive index of the passivation layer 110 and/or light guide 120.

In some implementations, the thickness of the passivation layer 110 may be about 50 nm or more, about 75 nm or more, or about 75-125 nm. In some other implementations, the thickness of the passivation layer 110 may be about 250-330 nm. Such thicknesses have been found to provide benefits for providing anti-reflective properties in the optical spectrum to the passivation layer 110, as discussed herein. By forming the passivation layer 110 conformally over the light guide 120, the passivation layer 110 may be formed to a substantially uniform thickness, thereby consistently providing anti-reflective properties within the desired optical spectrum across the light guide 120. In some implementations where the thickness of the passivation layer 110 varies between the bottom and the sidewalls of a light turning feature 121, the above-noted thicknesses may be the thickness at the bottom of the light turning feature 121. In some implementations, the thickness of the passivation layer 110 at the bottom of the light turning feature 121 may about 100 nm, or about 290 nm, and the thickness of the passivation layer 110 at the sidewalls of the light turning feature 121 is within about 40 nm, or about 25 nm of the thickness at the bottom.

The illumination system may include an underlying display 160 for which the anti-reflection properties of the light guide 120 may provide benefits. As discussed herein, light from the light source 130 may be injected into the light guide 120, redirected by the light turning features 121 towards the display 160, and reflected by the display 160 forwards towards the viewer 170, thereby forming an image perceived by the viewer 170. The anti-reflective properties provided by the optical decoupling layer 180a, passivation layer 110, and light guide 120 can reduce the reflections seen by the viewer 170, thereby improving the perceived contrast of the display 160.

With reference to FIG. 12, a plot of reflectivity versus thickness for a silicon oxide passivation layer situated directly on a light guide is shown. The silicon oxide passivation layer (refractive index 1.47) is disposed between an overlying optically transmissive layer (for example, a silicone layer, (refractive index=1.42) and an underlying optically transmissive layer (for example, a SiON layer, refractive index 1.52) in an underlying light guide. With the refractive index of the passivation layer at such an intermediate value, the passivation layer can give exceptional antireflective properties. For example, at thicknesses of about 75-125 nm, a 14-fold decrease in reflectivity is observed in comparison to not having a passivation layer at all. Moreover, this decrease is observed for light striking the passivation layer at angles of incidence from 0° (relative to the normal) to 30° (relative to the normal). In addition, at similar thicknesses (for example, about 75-125 nm), the decrease in reflectivity is similar for this range of angles, indicating that a single passivation layer with a single thickness may achieve similar reductions in reflectivity for a wide range of incident angles. Beneficial reductions in reflectivity are also observed at higher thicknesses. For example, at thicknesses of about 275-325 nm, a 7-fold decrease in reflectivity is observed, and at thicknesses of about 470-500 nm, greater than a 3-fold decrease in reflectivity is observed.

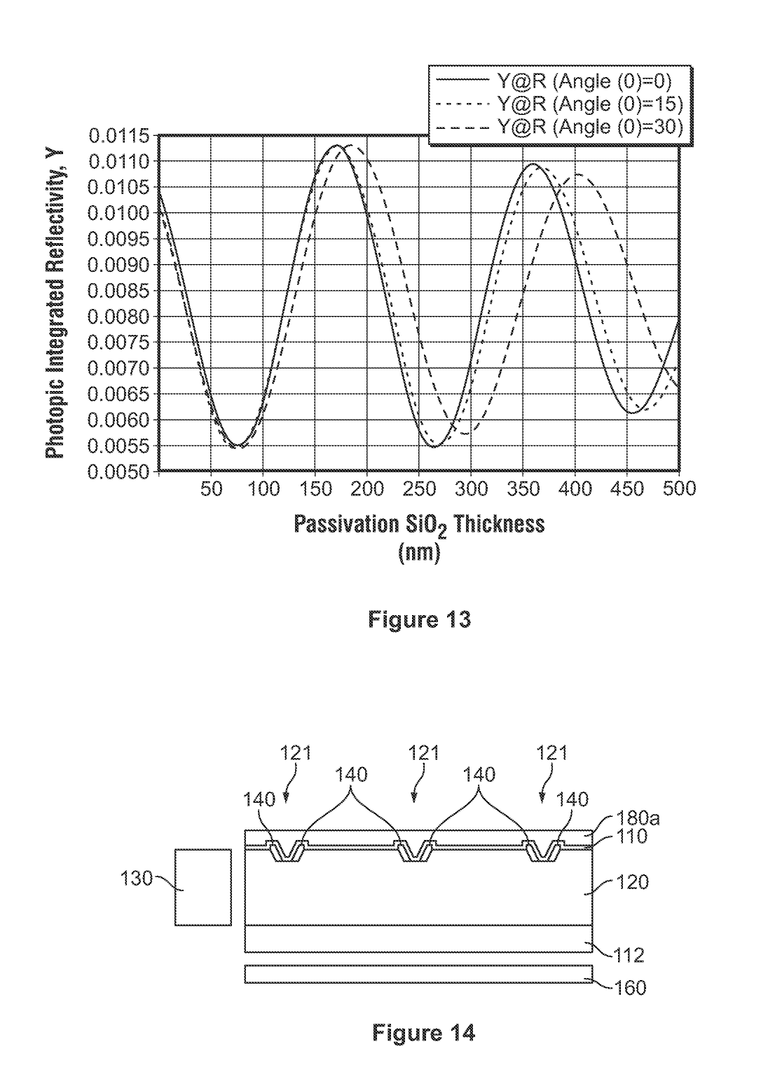

FIG. 13 shows a plot of reflectivity versus thickness for a silicon oxide passivation layer situated directly on a light turning feature. The light turning feature includes coating 140 (FIG. 9B) that include a 50 nm reflective layer of a reflective layer (for example, Al), a 72 nm spacer layer of an optically transmissive spacer layer (for example, silicon oxide), and a 5 nm partially reflective layer of a thin metal (for example, MoCr). Overlying the passivation layer is a layer of silicone (refractive index=1.42). The passivation layer is formed of silicon oxide. As seen in FIG. 13, these layers achieve good antireflective properties. At thicknesses of about 165-185 nm, a halving of the reflectivity is observed in comparison to not having a passivation layer at all. Decreases in reflectivity are observed for light striking the passivation layer at angles of incidence from 0° (relative to the normal) to 30° relative to the normal. Similar decreases are observed at similar thicknesses (for example, about 50-100 nm), such that a single passivation layer with a single thickness may achieve similar reductions in reflectivity for a wide range of incident angles. Also, these thicknesses overlap the thicknesses that provide significant reductions in reflectivity for passivation layers directly on the light guide (see FIG. 12). For example, thicknesses of about 50-110 nm, or about 75-100 nm may provide high levels of anti-reflectivity for a passivation layer distributed on a light guide and on a light turning feature.

With continued reference to FIG. 13, larger thicknesses also provide reductions in reflectivity. For example, at thicknesses of about 260-300 nm, a roughly 50% decrease in reflectivity is observed, and at thicknesses of about 450 nm, a roughly 40% decrease in reflectivity is observed.

Whether as part of an anti-reflective structure or implemented without anti-reflective functionality, it will be appreciated that the passivation layer 110 may be arranged in various configurations. FIG. 14 shows an example of a cross-section of an illumination system with multiple passivation layers. The passivation layer 110 is disposed over the light guide 120 and another passivation layer 112 is disposed under the light guide 120. In some implementations, the passivation layer 112 has a thickness and refractive index which allows that layer 112 to act as an anti-reflective coating, as discussed herein for the passivation layer 110. In some implementations, the thickness of the passivation layer 112 may be about 75 nm or more, or about 75-125 nm, or about 250-330 nm. In addition, the passivation layer 112 may have a refractive index less than that of the immediately overlying layer 129 of the light guide 120. A lower refractive index optical decoupling layer (such as the layer 180b, FIG. 11) may be provided under the passivation layer 112. In some other implementations, an air gap acts as the optical decoupling layer.

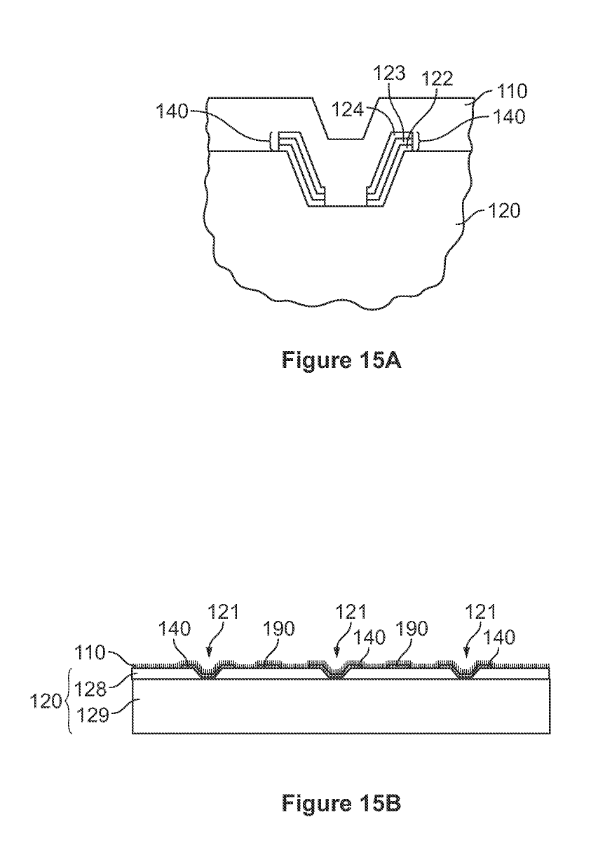

With reference to FIGS. 15A and 15B, the passivation layer 110 may be a blanket layer disposed directly over the coating 140 of the light turning feature 121 and extending continuously on the portions of the light guide 120 extending between light turning features 121. FIGS. 15A and 15B show an example of a cross-section of light turning feature 121 and light guide 120 having an overlying passivation layer 110. The coating 140 of the light turning features 121 may be formed of a plurality of layers 122, 123 and 124, as discussed herein. The passivation layer 110 extends substantially across the entirety of the light guide 120. With reference to FIG. 15B, in addition to the light turning features 121, various other features may be present on the surface of the light guide 120. For example, conductive features 190 may be provided over the light guide 120. The conductive features 190 may include, for example, interconnects or electrodes. The features 190 may form part of, for example, a touchscreen display.

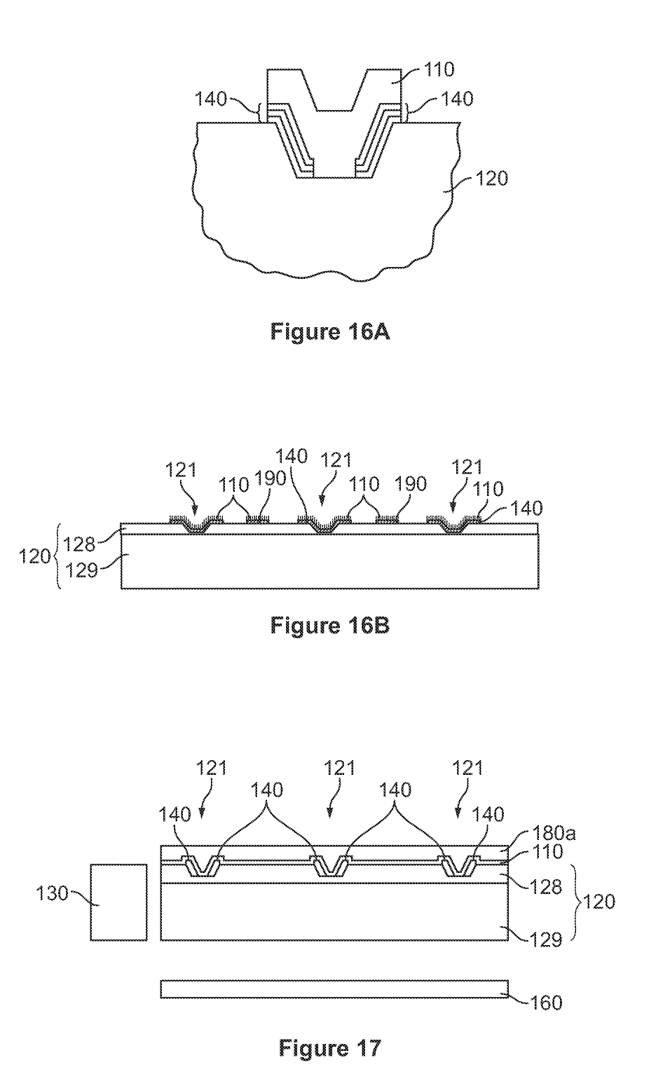

In some other implementations, the passivation layer 110 may be patterned after being deposited. FIGS. 16A and 16B show an example of a cross-section of an illumination system with light turning feature 121 and light guide 120 having an overlying patterned passivation layer 110. In some implementations, the passivation layer 110 is patterned such that portions of it are localized substantially at the light turning features 121, while portions of the passivation layer 110 in the areas between light turning features 121 are substantially removed.

In some implementations, each of the layers forming the coating 140 and the passivation layer 110 may be blanket deposited over the light guide 120. These layers may then be simultaneously patterned using a single mask, which allows the coating 140 and passivation layer 110 to be simultaneously defined by etching. The patterned passivation layer 110 caps the light turning feature 121 and coating 140. As illustrated in FIGS. 16A and 16B, the sidewalls of the patterned passivation layer 110 and the coating 140 may be substantially coplanar, such that the sides of the coating 140 are exposed or unprotected by the patterned passivation layer 110. In addition, conductive features 190 may be present over the light guide 120. The features 190 may also be patterned simultaneously with the patterned passivation layer 110, such that the sidewalls of the passivation layer 110 and the features 190 may be coplanar and the sides of the features 190 are exposed or unprotected by the patterned passivation layer 110.

A person having ordinary skill in the art will recognize that the exposed sides of the coatings 140 may leave those sides susceptible to interactions with moisture and gases from the ambient environment. However, these layers may have thicknesses on the order of tens of nanometers, while the widths of the light turning features 121 are on the order of microns. Thus, corrosion or reactions at the side of the coating 140 are not believed to progress at a rate sufficient to undermine the functionality of the light turning features 121 over the expected life of the illumination system containing the coating 140.

Patterning the passivation layer 110 can facilitate the formation of ancillary structures in the openings left by removed parts of the passivation layer 110. In some implementations, the passivation layer 110 is patterned to facilitate electrical contacts to underlying electrical features. FIG. 16B shows an example of a cross-section of an illumination system with a patterned passivation layer 110. The light guide 120 may be overlaid with conductive features, such as interconnects or electrodes (not shown) which allow the illumination system to function as a touch screen. Openings patterned into the passivation layer 110 may be used to form contacts between the interconnects or electrodes and overlying conductive features.

While referred to herein as a single entity for ease of discussion and illustration, it will be appreciated that the light guide 120 may be formed of one or more layers of material. FIG. 17 shows an example of a cross-section of an illumination system with a multilayer light guide. The light guide 120 can be formed of a light turning film 128 and an underlying supporting layer 129. Both the turning film 128 and supporting layer 129 may be formed of a substantially optically transmissive material that allows light to propagate along the length thereof. For example, the turning film 128 and the supporting layer 129 may each include one or more of the following materials: acrylics, acrylate copolymers, UV-curable resins, polycarbonates, cycloolefin polymers, polymers, organic materials, inorganic materials, silicates, alumina, sapphire, glasses, polyethylene terephthalate (“PET”), polyethylene terephthalate glycol (“PET-G”), silicon oxy-nitride, and/or other optically transparent materials. For mechanical and chemical stability, the material forming the turning film 128 may have a low moisture absorption, thermal and chemical resistance to materials and temperatures used in later processing steps, and limited or substantially no out-gassing. In some implementations, the turning film 128 is formed of a material depositable as a liquid, such that the material can be deposited in the liquid phase on the supporting layer 129. In some implementations, the material forming the turning film 128 may be a glass, for example, a spin-on glass. In some implementations, the material forming the turning film 128 may be photodefinable, for example, being formed of a photodefinable spin-on glass and/or a photodefinable polymer. As used herein, a spin-on material is a material that may be deposited by a spin-on deposition, in which the material is deposited on a spinning underlying support, such as the supporting layer 129. However, the spin-on material need not be deposited by a spin-on deposition. For example, in some implementations, the spin-on material may be deposited on a stationary supporting layer 129. In either case, in some implementations, the spin-on material may be deposited as a liquid on the supporting layer 129. The liquid may be a solution for which solvent is removed, for example in a curing process, to form a solid-phase turning film 128.

In some implementations, the turning film 128 and the supporting layer 129 are formed of the same material and in other implementations, the turning film and the supporting layer 129 are formed of different materials. In some implementations, the turning film 128 may be formed of spin-on glass, or a photodefinable polymer, and the supporting layer 129 may be formed of glass. In some implementations, the indices of refraction of the turning film 128 and the supporting layer 129 may be matched to be close or equal to one another such that light may propagate successively through the layers substantially without being reflected or refracted at the interface between the layers. In some implementations, the refractive indices of the turning film 128 and the support layer 129 are within about 0.05, about 0.03, or about 0.02 of each other. In one implementation, the supporting layer 129 and the turning film 128 each have an index of refraction of about 1.52. According to some other implementations, the indices of refraction of the supporting layer 129 and/or the turning film 128 can range from about 1.45 to about 2.05. In some implementations, the supporting layer 129 and turning film 128 may be held together by an adhesive (for example, a pressure-sensitive adhesive), which may have an index of refraction similar or equal to the index of refraction of one or both of the supporting layer 129 and turning film 128. In addition, in some implementations, the display 160 may be laminated to the light guide 120 using a refractive-index matched adhesive, such as a pressure-sensitive adhesive (“PSA”).

One or both of the supporting layer 129 and the turning film 128 can include one or more light turning features 121. In some implementations, the light turning features 121 are disposed on a top surface of the light turning film 128. The indentations forming these features 121 may be formed by various processes, including etching and embossing. The thickness of the light turning film 128 can be sufficient to form the entire volume of the light turning features 121 within that film. In some implementations, the light turning film 128 has a thickness of about 1.0-5 μm, about 1.0-4 μm, or about 1.5-3 μm.

In addition, the coating 140 on the walls of the light turning features 121 may be formed by depositing (for example, blanket depositing) one or more films of the desired materials and then etching the deposited film to remove the materials from locations outside of the light turning features 121. The formation of the indentations and/or the formation of the coating 140 can be performed before attaching the turning film 129 to the support layer 129. In some implementations, this can facilitate fabrication of the illumination system, since defects in the indentations or the coating 140 can be discovered before attaching the turning film 128 to the supporting layer 129 and the remainder of the illumination system. Thus, rather than discarding the entire light guide 120 and/or other parts attached to the turning film 129 when a defect in the light turning features 121 is found, only a defective turning film 129 may need to be replaced.

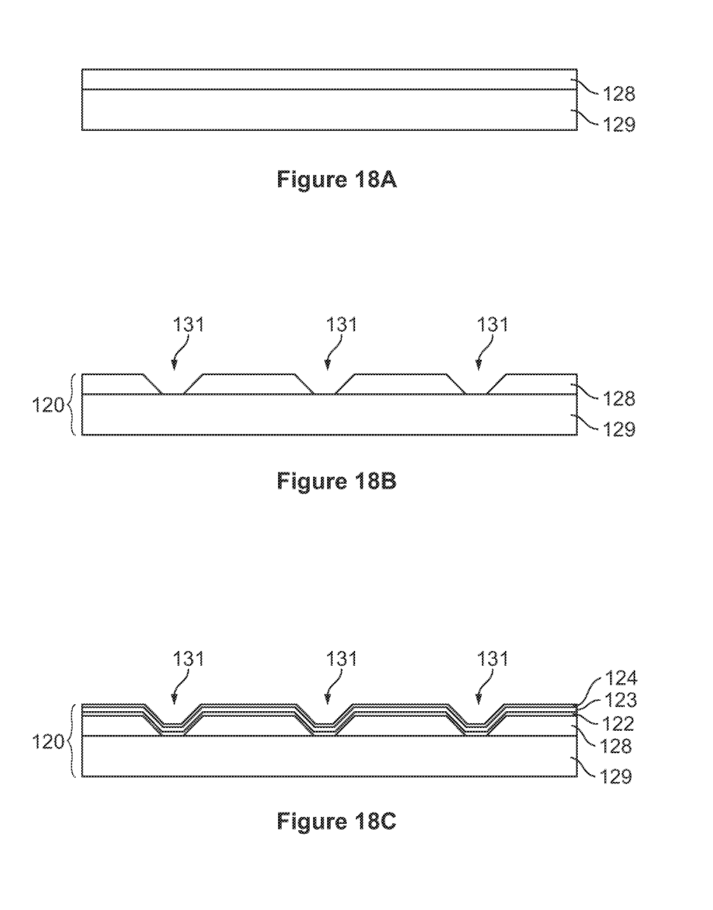

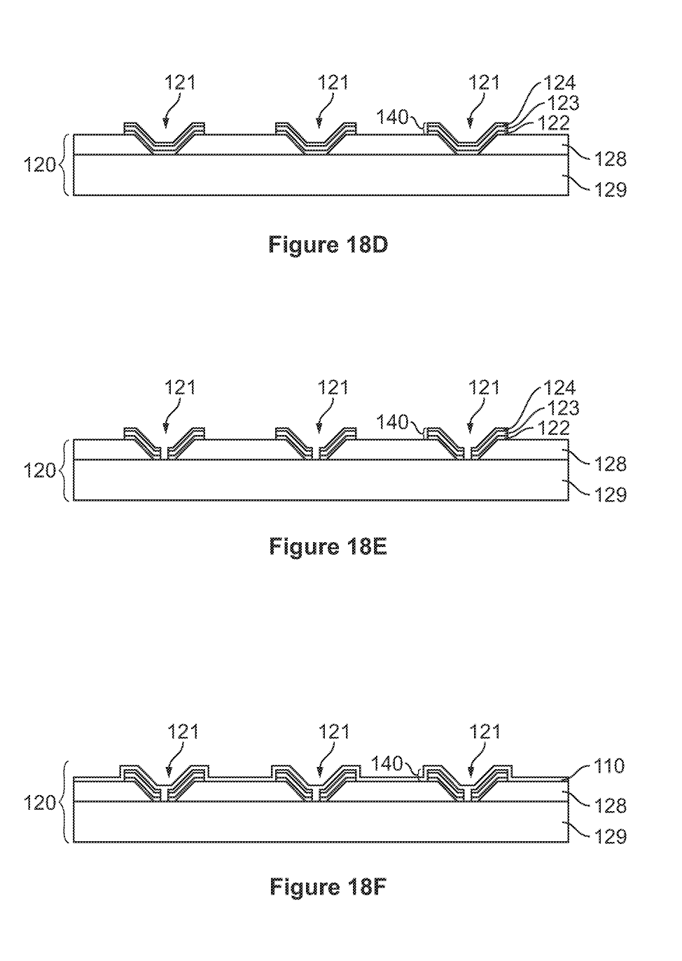

In some other implementations, the light guide may be etched to define light turning features after the turning film 129 is combined with a supporting layer 128. With reference now to FIGS. 18A-18F, examples of cross-sections of an illumination system at various stages in a process sequence for manufacturing the illumination system are shown. With reference to FIG. 18A, the light turning film 128 is provided disposed on the supporting layer 129. In some implementations, the light turning film 128 is formed of a glass, such as a spin-on glass. The material forming the light turning film 128 may be photodefinable, including a photodefinable glass, such as a photodefinable spin-on glass. In some other implementations, the photodefinable material is a non-glass material and may be, for example, a photodefinable polymer.

FIG. 18B shows the light turning film 128 after patterning that film to form indentations 131. The indentations 131 may be formed by photolithography in which the light turning film 128 is exposed to light through a reticle and then the light turning film is exposed to a development etch, which may be a wet etch, to remove selected portions of the light turning film 128 to form indentations 131. In some implementations, the size and shape of the indentations 131 can be controlled by modifying the process of exposing and developing the photodefinable material forming the light turning film 128.

FIG. 18C shows the light turning film 128 and indentations 131 of FIG. 18B after blanket depositing one or more layers of material on the light turning film 128. As illustrated, the layers 122, 123, and 124 may be sequentially deposited to form an interferometric stack that functions as a reflector for light propagating within the supporting layer 129 and the light turning film 128, and that also functions as a black mask to a viewer, as described herein.

FIG. 18D shows the layers 122, 123, and/or 124 after etching the layers 122, 123, and/or 124 to substantially remove the portions of those layers outside of the indentations 131 (FIG. 18C), thereby defining the coating 140 as part of light turning features 121. As shown in FIG. 18E, the portions of the layers 122, 123, and/or 124 in the middle parts of the indentations 131 and that are not on the sidewalls of the indentations 131 may also be etched to permit light to travel though those middle parts.

As shown in FIG. 18F, passivation layer 110 may be deposited on the layer 128 and into the light turning features 121. In some implementations, the passivation layer 110 is conformal. In some other implementations, the passivation layer 110 fills the light turning features 121 and functions as a planarization layer (not shown) by providing a planar surface over the indentations and major surface of the light guide 120. In some implementations, the planarization layer may be formed of a spin-on glass material, and may have a low refractive index to function as an optical decoupling layer. In some implementations, the passivation layer 110 functions as a moisture barrier, as discussed herein.

It will be appreciated that the use of glass or photodefinable materials in come implementations can provide benefits over the use of chemical vapor deposited materials. The use of photodefinable materials (including photodefinable glass materials) or non-photodefinable glass materials allows the light turning film to be formed by a relatively fast bulk deposition, for example, by a spin-on coating process, rather than a slower chemical vapor deposition. In addition, in some implementations, the light turning film may be more quickly etched than some chemical vapor deposited materials. For example, the photodefinable materials may be etched using a development etched, which may be a wet etch. Also, because the light turning film is itself photodefinable, a separate mask formation and pattern transfer step is not required to define indentations in the light turning film. As a result, the manufacturing throughput can be increased, thereby reducing manufacturing costs. In addition, the cost of the materials may be lower than that of chemical vapor deposited materials, thereby further reducing manufacturing coats.

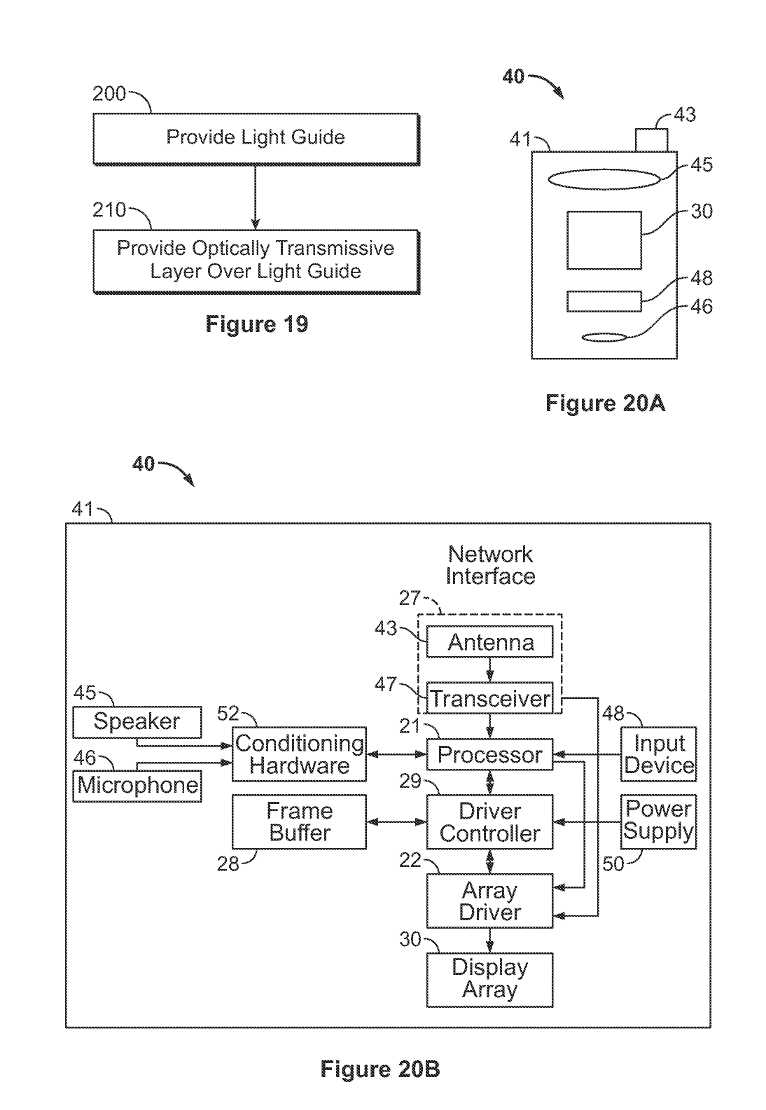

It will be appreciated that the illumination systems described herein may be manufactured in various ways. FIG. 19 shows an example of a flow diagram illustrating a manufacturing process for an illumination system. A light guide is provided 200. An optically transmissive passivation layer is provided 210 disposed over a major surface of the light guide. The passiviation layer is a moisture barrier as described herein. The light guide may correspond to the light guide 120 (see, for example, FIGS. 9A-11 and 14-19F), as described herein. The passivation layer may correspond to the passivation layer 110 (see, for example, FIGS. 10-11, 14-17, and 18F), as descried herein.

Providing the light guide 200 can encompass providing a light guide as a panel. The light guide may be provided with a plurality of light turning features, such as the features 121 (FIGS. 9A-11, 14-17, and 18D-18F). These features may be formed by etching the panel to define indentations for the features, and then optionally depositing and patterning the coating 140 (FIGS. 9A-11, 14-17, and 18D-18E) on the walls of the indentations. In some implementations, the passivation layer 110 is deposited before patterning the coating 140. The passivation layer 110 may then be simultaneously patterned with the coating 140.

In some other implementations, the light turning features 121 may be formed in a light turning film 128 that is later attached to an underlying supporting layer. Thus, formation of the indentations for the light turning features may be performed before attachment to the supporting layer. In some implementations, the coating 140 and/or passivation layer 110 may be applied before attachment to the supporting layer. In other implementations, the coating 140 and/or passivation layer 110 may be applied after attachment to the supporting layer.

Providing the passivation layer 110 may include depositing the passivation layer 110 on the light guide. The deposition may be accomplished by various methods known in the art, including chemical vapor deposition. In some implementations, the top surface of the light guide 120 is coated with the passivation layer 110. In some other implementations, both the top and bottom surfaces of the light guide 120 are coated with a passivation layer. Coating both the top and bottom surfaces of the light guide 120 may include separately depositing the passivation layer 110 on each surface, or may include simultaneously coating other surfaces with the passivation layer 110. For example, the light guide 120 may be subjected to a wet coating process in which both surfaces of the light guide 120 are simultaneously exposed to the coating agent to form a passivation layer 110 on each side of the light guide 120. In some implementations, the extent of the coating or deposition process is gauged such that the final passivation layer 110 has a thickness of about 50 nm or greater for use as both a moisture barrier and an anti-reflective coating.

FIGS. 20A and 20B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 20B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (for example, filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (for example, an IMOD controller). Additionally, the array driver 22 can be a conventional driver or a bi-stable display driver (for example, an IMOD display driver). Moreover, the display array 30 can be a conventional display array or a bi-stable display array (for example, a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, for example, a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An illumination system, comprising:
a light guide including:
an optically transmissive supporting layer; and
a light turning film on the supporting layer, the light turning film formed of a material depositable in the liquid phase on the supporting layer; and
a plurality of light turning features formed in indentations in the light turning film.

2. The illumination system of claim 1, wherein the light turning film is formed of a glass material.

3. The illumination system of claim 2, wherein the glass is a spin-on glass material.

4. The illumination system of claim 2, wherein the spin-on glass material is a photodefinable spin-on glass material.

5. The illumination system of claim 1, wherein the light turning film is formed of a photodefinable polymer.

6. The illumination system of claim 1, wherein the supporting layer and the light turning film have substantially matching refractive indices.

7. The illumination system of claim 1, wherein the supporting layer is formed of glass.

8. The illumination system of claim 1, further comprising an optically transmissive passivation layer on the light turning film.

9. The illumination system of claim 8, wherein the optically transmissive passivation layer is a glass layer.

10. The illumination system of claim 9, wherein the glass layer is formed of a spin-on glass.

11. The illumination system of claim 8, wherein the passivation layer has a thickness of about 250-330 nm.

12. The illumination system of claim 1, further comprising a reflective layer disposed directly on surfaces of the indentations.

13. The illumination system of claim 12, wherein the reflective layer forms a black mask, the black mask including:
the reflective layer;
an optically transmissive spacer layer over the reflective layer; and
a second reflective layer over the spacer layer.

14. The illumination system of claim 1, further comprising a display, wherein the light turning features are configured to eject light out of the supporting layer and towards the display.

15. The illumination system of claim 14, wherein the display is a reflective display.

16. The illumination system of claim 14, wherein the reflective display includes an array of interferometric modulator display elements.

17. The illumination system of claim 14, further comprising:
a processor that is configured to communicate with the display, the processor being configured to process image data; and
a memory device that is configured to communicate with the processor.

18. The apparatus as recited in claim 17, further comprising:
a driver circuit configured to send at least one signal to the display.

19. The apparatus as recited in claim 18, further comprising:
a controller configured to send at least a portion of the image data to the driver circuit.

20. The apparatus as recited in claim 17, further comprising:
an image source module configured to send the image data to the processor.

21. The apparatus as recited in claim 20, wherein the image source module comprises at least one of a receiver, transceiver, and transmitter.

22. The apparatus as recited in claim 17, further comprising:
an input device configured to receive input data and to communicate the input data to the processor.

23. An illumination system, comprising:
a light guide including:
an optically transmissive supporting layer; and
a means for accommodating indentations for light turning features, wherein the means for accommodating indentations is depositable in a liquid state.

24. The illumination system of claim 23, wherein the means for accommodating indentations is a light turning film formed of spin-on glass.

25. The illumination system of claim 23, wherein the means for accommodating indentations is a light turning film formed of a photo-definable polymer.

26. The illumination system of claim 25, further comprising a passivation layer on the photo-definable polymer, wherein the passivation layer has a thickness of about 250-330 nm.

27. A method for forming an illumination system, comprising:
providing an optically transmissive supporting layer;
depositing a liquid material on the support layer to form a light turning film; and
defining indentations in the light turning film to form a plurality of light turnings features in the light turning film.

28. The method of claim 27, wherein providing the optically transmissive support layer includes providing a glass layer.

29. The method of claim 27, wherein depositing the liquid material includes depositing a spin-on glass material.

30. The method of claim 27, wherein depositing the liquid material includes depositing a photodefinable polymer.

31. The method of claim 27, wherein the light turning film is a solid phase film, further comprising curing the liquid material to form the solid phase film.

32. The method of claim 27, wherein defining indentations includes:
exposing the light turning film to light through a reticle; and
subsequently exposing the light turning film to a development etch to form the indentations.

33. The method of claim 27, wherein defining indentations in the light turning film to form the plurality of light turnings features includes coating surfaces of the indentations with one or more reflective layers.

34. The method of claim 33, further comprising depositing a passivation layer over the one or more reflective layers.

35. The method of claim 34, wherein the passivation layer has a thickness of about 250-330 nm.

36. The method of claim 27, further comprising attaching a light source to an edge of the light guide.

37. The method of claim 36, further comprising attaching a display facing a major surface of the light guide.
